(19) United States
(12) Patent Application Publication
(10) Pub. No.: US 2024/0069428 A1
(43) Pub. Date: Feb. 29, 2024

(54) REFLECTIVE MASK BLANK, REFLECTIVE MASK, REFLECTIVE MASK MANUFACTURING METHOD, AND SEMICONDUCTOR DEVICE MANUFACTURING METHOD

(71) Applicant: HOYA CORPORATION, Tokyo (JP)

(72) Inventor: Yohei IKEBE, Tokyo (JP)

(73) Assignee: HOYA CORPORATION, Tokyo (JP)

(21) Appl. No.: 18/039,466

(22) PCT Filed: Dec. 8, 2021
(86) PCT No.: PCT/JP2021/045162

§ 371 Date: May 30, 2023

(30) Foreign Application Priority Data
Dec. 22, 2020 (JP) 2020-212297

(51) Int. Cl. G03F 1/24; C03C 17/22; C03C 17/36; C23C 14/06; C23C 14/08; C23C 14/18; C23C 14/35; C23C 14/46; G03F 1/74; G03F 1/84

(52) U.S. Cl. CPC G03F 1/24; C03C 17/225; C03C 17/3636; C03C 17/3649; C03C 17/3665; C23C 14/0641; C23C 14/083; C23C 14/185; C23C 14/35; C23C 14/46; G03F 1/74; G03F 1/84; C03C 2218/155; C03C 2218/156; C03C 2218/365

(57) ABSTRACT

A reflective mask blank includes a multilayer reflective film, a first thin film, and a second thin film in this order on a main surface of a substrate, a relative reflectance R₂ of the second thin film with respect to a reflectance of the multilayer reflective film in the light of 13.5 nm wavelength is 3% or more, and an extinction coefficient k₁ of the first thin film in the light of 13.5 nm wavelength and a thickness d₁ [nm] of the first thin film satisfy a relationship of (Formula 1).

21.5×k₁²×d₁²−52.5×k₁×d₁+32.1>R₂ (Formula 1)

### CROSS-REFERENCE TO RELATED APPLICATIONS

This application is the National Stage of International Application No. PCT/JP2021/045162, filed Dec. 8, 2021, which claims priority to Japanese Patent Application No. 2020-212297, filed Dec. 22, 2020, and the contents of which is incorporated by reference.

### TECHNICAL FIELD

The present disclosure relates to a reflective mask blank which is an original plate for manufacturing an exposure mask used for manufacturing a semiconductor device or the like, to a reflective mask, to a method of manufacturing a reflective mask, and to a method of manufacturing a semiconductor device.

### BACKGROUND ART

Exposure apparatuses for manufacturing semiconductor devices have advanced with the wavelength of a light source is gradually shortening. To implement finer pattern transfer, EUV lithography using extreme ultra violet (EUV, hereinafter, sometimes referred to as EUV light) having a wavelength of about 13.5 nm, has been developed. In EUV lithography, reflective masks are used because there are few materials transparent to EUV light. Representative reflective masks include a reflective binary mask and a reflective phase shift mask (reflective halftone phase shift mask). The reflective binary mask has a relatively thick absorber pattern that sufficiently absorbs EUV light. The reflective phase shift mask has a relatively thin absorber pattern (phase shift pattern) that absorbs and attenuates EUV light and generates reflected light whose phase is inverted at a desired angle with respect to reflected light from the multilayer reflective film. In the reflective phase shift mask, since a high transfer optical image contrast is obtained by a phase shift effect, resolution can be further improved. Furthermore, since the film thickness of the absorber pattern (phase shift pattern) of the reflective phase shift mask is thin, a fine phase shift pattern can be formed with high precision.

Patent Documents 1 and 2 disclose technologies related to such reflective masks for EUV lithography and mask blanks for producing the reflective masks.

Patent Document 1 discloses a reflective mask blank including a multilayer reflective film, an absorber film, and an etching mask film in this order on a substrate, in which, to obtain the absorber film having a reflectance of 2% or less with respect to EUV light, the absorber film includes a buffer layer and an absorption layer provided on the buffer layer, the buffer layer is made of a material containing tantalum (Ta) or silicon (Si) and the buffer film has a thickness from 0.5 nm or more to 25 nm or less, the absorption layer is made of a material containing chromium (Cr) and has an extinction coefficient greater than the extinction coefficient of the buffer film with respect to EUV light, and the etching mask film is made of a material containing tantalum (Ta) or silicon (Si) and has a film thickness from 0.5 nm to 14 nm.

Patent Document 2 discloses a reflective mask blank including a multilayer reflective film, a protective film, and a phase shift film for shifting the phase of EUV light in this order on a substrate. The phase shift film includes a first layer and a second layer, the first layer is made of a material containing at least one element of tantalum (Ta) and chromium (Cr), and a second layer is made of a material containing a metal containing ruthenium (Ru) and at least one element of chromium (Cr), nickel (Ni), cobalt (Co), vanadium (V), niobium (Nb), molybdenum (Mo), tungsten (W), and rhenium (Re).

### PRIOR ART PUBLICATIONS

### Patent Documents

Patent Document 1: WO 2020/175354
Patent Document 2: WO 2019/225737

### SUMMARY OF THE DISCLOSURE

### Problems to be Solved by the Disclosure

The finer the pattern and the higher the precision of the pattern dimension and pattern position, the higher the electrical characteristics and performance of the semiconductor device, and the higher the degree of integration and the smaller the chip size. Therefore, EUV lithography is required to have a pattern transfer performance for achieving higher precision and finer dimensions than those in the related art. At present, formation of ultrafine and highly precise patterns corresponding to the hp 16 nm (half pitch 16 nm) generation is required. To meet such requirements, a reflective phase shift mask is required in which EUV light is used as exposure light and a phase shift effect is further used.

When a reflective mask including ultrafine and highly precise patterns is manufactured using a reflective mask blank, patterns are formed in an absorber film by dry etching. However, it is difficult to form all patterns in the absorber film with high precision, and it is difficult to avoid the occurrence of so-called black defects in which the absorber film in a region to be removed by etching is not removed after the patterning of the absorber film. Such a black defect in the absorber pattern can often be repaired by defect repair techniques. In recent years, defect repair (EB defect repair) is often used in which the black defect is volatilized and removed by irradiating the black defect with charged particles such as electron beams while supplying a non-excited etching gas (fluorine-based gas or the like) to the periphery of the black defect. However, depending on the constituent elements of the absorber film, a repair rate difference between the absorber film and a protective film may not be sufficiently secured when the black defect is repaired by EB defect repair. On the other hand, in recent years, various materials have been studied for forming the absorber film. Depending on the material of the absorber film, sufficient etching selectivity may not be secured between the absorber film and the protective film during dry etching when patterning the absorber film.

Under these circumstances, a buffer film having sufficient etching selectivity with respect to both the protective film and the absorber film may be provided between the protective film and the absorber film. In a step of manufacturing a reflective mask from the reflective mask blank including the buffer film, after a step of forming a transfer pattern in the absorber film by dry etching is performed and before a step of forming a transfer pattern in the buffer film by dry etching is performed, mask inspection (defect inspection), which includes an inspection of confirming the presence or absence of black defects in the absorber pattern, is performed. In this mask inspection, a region where the absorber film is present on a substrate is detected from the contrast between reflected light from a region where the absorber film is present with respect to inspection light and reflected light from a region where the absorber film is removed and the buffer film is exposed with respect to inspection light. Therefore, to perform a highly precise defect inspection, sufficient contrast needs to be secured between the reflected light from the absorber film with respect to the inspection light and the reflected light from the buffer film with respect to the inspection light. In addition, a mask blank for a reflective mask has an optical restriction because the transfer pattern is formed by a layered structure with the absorber film, the buffer film, and the absorber film. Particularly, in the case of a reflective phase shift mask, an entire transfer pattern of the layered structure with the buffer film and the absorber film needs to exhibit a desired phase shift function. Under these circumstances, there is a demand for providing a reflective mask blank to which a highly precise mask inspection can be performed while satisfying the optical properties for EUV light required for a reflective mask.

Therefore, an aspect of the present disclosure is to provide a reflective mask blank to which a highly precise mask inspection can be performed while satisfying optical properties required for a reflective mask.

Another aspect of the present disclosure is to provide a reflective mask manufactured using the above reflective mask blank, a method of manufacturing the reflective mask, and a method of manufacturing a semiconductor device using the reflective mask.

### Means for Solving the Problem

To solve the abovementioned problems, the present disclosure has the following configuration.

### Configuration 1

A reflective mask blank including a multilayer reflective film, a first thin film, and a second thin film in this order on a main surface of a substrate, in which
a relative reflectance R₂ of the second thin film relative to a reflectance of the multilayer reflective film with respect to light having a wavelength of 13.5 nm is 3% or more, and
when an extinction coefficient of the first thin film with respect to the light having a wavelength of 13.5 nm is k₁ and a thickness of the first thin film is d₁ [nm], a relationship of Formula 1 is satisfied.

21.5×k₁²×d₁²−52.5×k₁×d₁+32.1>R₂ (Formula 1)

### Configuration 2

The reflective mask blank according to configuration 1, in which the relative reflectance R₂ is 32% or less.

### Configuration 3

The reflective mask blank according to configuration 1 or 2, in which the extinction coefficient k₁ of the first thin film is 0.05 or less.

### Configuration 4

The reflective mask blank according to any one of configurations 1 to 3, in which the thickness d₁ of the first thin film is 1 nm or more and 30 nm or less.

### Configuration 5

The reflective mask blank according to any one of configurations 1 to 4, in which the first thin film contains a metal element and at least one element of oxygen and nitrogen.

### Configuration 6

The reflective mask blank according to any one of configurations 1 to 5, in which the second thin film contains a metal element.

### Configuration 7

The reflective mask blank according to any one of configurations 1 to 6, including a protective film between the multilayer reflective film and the first thin film.

### Configuration 8

The reflective mask blank according to configuration 7, in which the protective film contains ruthenium.

### Configuration 9

A reflective mask in which a transfer pattern is formed in the first thin film and the second thin film of the reflective mask blank according to any one of configurations 1 to 8.

### Configuration 10

A method of manufacturing a reflective mask using the reflective mask blank according to any one of configurations 1 to 8, the method including the steps of
forming a transfer pattern in the second thin film;
performing a defect inspection of the transfer pattern by using inspection light including light having a wavelength of 13.5 nm with respect to the second thin film in which the transfer pattern is formed;
performing a defect repair by irradiating defects detected by the defect inspection which exist in the transfer pattern of the second thin film with charged particles while supplying a fluorine-containing substance to the defects; and
forming a transfer pattern in the first thin film after the defect repair.

### Configuration 11

A method of manufacturing a semiconductor device, the method including the step of:
transferring a transfer pattern to a resist film on a semiconductor substrate by exposure using the reflective mask according to configuration 9.

### Configuration 12

A method of manufacturing a semiconductor device, the method including the step of:
transferring a transfer pattern to a resist film on a semiconductor substrate by exposure using the reflective mask manufactured by the method of manufacturing the reflective mask according to configuration 10.

### [Effect of the Disclosure]

According to the present disclosure, it is possible to provide a reflective mask blank to which a highly precise mask defect inspection can be performed while satisfying optical properties required for a reflective mask.

According to the present disclosure, it is possible to provide a reflective mask manufactured using the above reflective mask blank, a method of manufacturing the reflective mask, and a method of manufacturing a semiconductor device by using the reflective mask.

### BRIEF DESCRIPTION OF THE DRAWINGS

FIG. 1 is a schematic cross-sectional view of main components for explaining an example of the schematic configuration of a reflective mask blank according to an embodiment of the present disclosure.

FIGS. 2A-2D are process drawings illustrating a step of producing a reflective mask from a reflective mask blank with schematic cross-sectional views of main components.

FIG. 3 is a graph showing the relationship among the thicknesses of a buffer film, the relative reflectance of an absorber film and a contrast with respect to light having a wavelength of 13.5 nm when the buffer film is made of a TaBO material.

FIG. 4 is a graph showing the relationship among the thicknesses of a buffer film, the relative reflectance of an absorber film and a contrast with respect to light having a wavelength of 13.5 nm when the buffer film is made of a CrN material.

### EMBODIMENTS FOR CARRYING OUT THE DISCLOSURE

Hereinafter, embodiments of the present disclosure will be described, and first, the background of the present disclosure will be described. The present inventor has conducted intensive studies on means that can perform pattern defect repair while satisfying optical properties required for a reflective mask. Particularly, the case of a reflective phase shift mask which is more restricted in optical properties than a reflective binary mask was examined in detail. First, attention was paid to the matter that, to exhibit a desired phase shift function, the relative reflectance of an absorber film having a phase shift function (hereinafter, simply referred to as “absorber film”) relative to a multilayer reflective film with respect to EUV exposure light is required to be 3% or more.

On the other hand, in recent years, an inspection apparatus using EUV light for inspection as inspection light has been put to practical use. Since this inspection apparatus performs inspection by using light having the same wavelength as that of EUV light (light having a wavelength of 13.5 nm)(hereinafter, this may be referred to as EUV exposure light) used in an exposure apparatus for EUV lithography, defects that may cause a problem during exposure can be preferably ascertained compared to inspection apparatuses using other wavelengths. However, when the defect of an absorber pattern (phase shift pattern) is repaired in a state where a buffer film remains, absorption or attenuation occurs in the buffer film.

As a result of studies on this point, the present inventor has found that a contrast of greater than 40% between the absorber film and the buffer film is necessary for good mask inspection even in a state where the buffer film is present. The contrast is a value calculated by the following Formula. In this specification, the term “relative reflectance” refers to a relative reflectance when the reflectance [%] of a multilayer reflective film is taken as 100. ((relative reflectance [%] of buffer film−relative reflectance [%] of absorber film)/(relative reflectance [%] of buffer film+relative reflectance [%] of absorber film))×100

As a result of studies on conditions for obtaining a desired contrast, the present inventor has found that the relative reflectance of the absorber film, and the thickness and the extinction coefficient k of the buffer film are main factors.

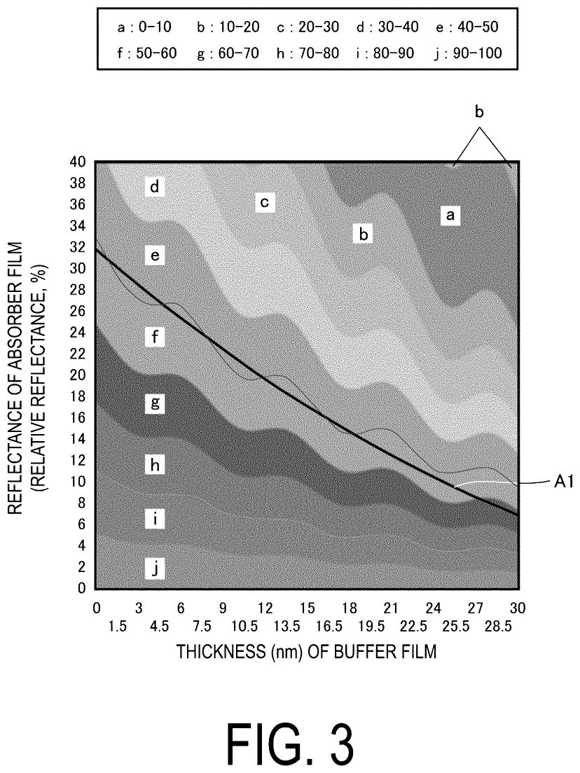

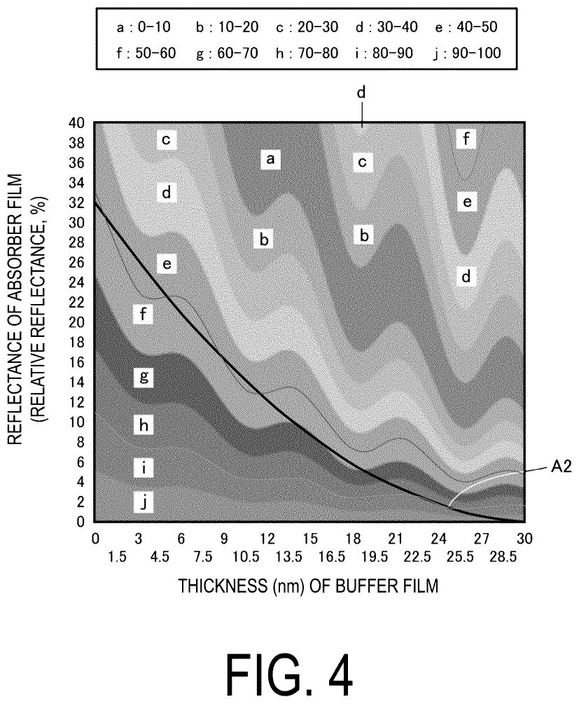

On the basis of this finding, the present inventor has found conditions for obtaining a desired contrast by simulation while changing the values of the thicknesses and the extinction coefficient k of the buffer film and the relative reflectance of the absorber film with respect to light having a wavelength of 13.5 nm. Examples thereof are each shown in FIGS. 3 and 4.

FIG. 3 is a graph showing the relationship among the thicknesses of a buffer film, the relative reflectance of an absorber film and the contrast with respect to light having a wavelength of 13.5 nm when the buffer film is made of TaBO. In FIG. 3, an extinction coefficient k₁ is set to 0.022 and a refractive index n₁ is set to 0.955, and then the contrast is simulated by changing the thicknesses of the buffer film from 0 nm to 30 nm and the relative reflectance of the absorber film from 0% to 40%.

FIG. 4 is a graph showing the relationship among the thicknesses of a buffer film, the relative reflectance of an absorption film, and the contrast when the buffer film is made of CrN. In FIG. 4, the extinction coefficient k₁ is set to 0.039 and the refractive index n₁ is set to 0.928, and then the contrast is simulated by changing the thicknesses of the buffer film from 0 nm to 30 nm and the relative reflectance of the absorber film from 0% to 40%.

In FIGS. 3 and 4, regions a, b, . . . j indicate regions having contrasts of 0 to 10, 10 to 20, . . . 90 to 100, respectively.

As a result of repeated studies by performing such various simulations, the present inventor has found that a desired contrast exceeding 40% can be obtained in a region in a range satisfying a Formula below.

21.5×k₁²×d₁²−52.5×k₁×d₁+32.1>R₂ (Formula 1)

Where k₁ denotes the extinction coefficient of the buffer film, d₁ denotes the thickness of the buffer film, and R₂ denotes the relative reflectance of the absorber film. A curve A1 in FIG. 3 and a curve A2 in FIG. 4 correspond to equal sign parts of Formula 1 above. That is, in FIG. 3, a desired contrast exceeding 40% is obtained in a region below the curve A1. In FIG. 4, a desired contrast exceeding 40% is obtained in a region below the curve A2. Even in the case of the reflective binary mask, a desired contrast exceeding 40% is obtained as long as the condition of Formula 1 above is satisfied.

Based on the above intensive studies, the present disclosure has been made. Note that, in the present embodiment, the buffer film is a first thin film and the absorber film is a second thin film; however, the present disclosure is not limited thereto.

Next, embodiments of the present disclosure will be described in detail with reference to drawings. Note that the embodiments described below are only examples of the present disclosure, and the present disclosure is not limited to these embodiments in any way. Note that the same reference numerals are used for components that are the same or equivalent in the drawings, and descriptions of such components will be simplified or omitted.

### Configuration of Reflective Mask Blank 100 and Method of Manufacturing Thereof

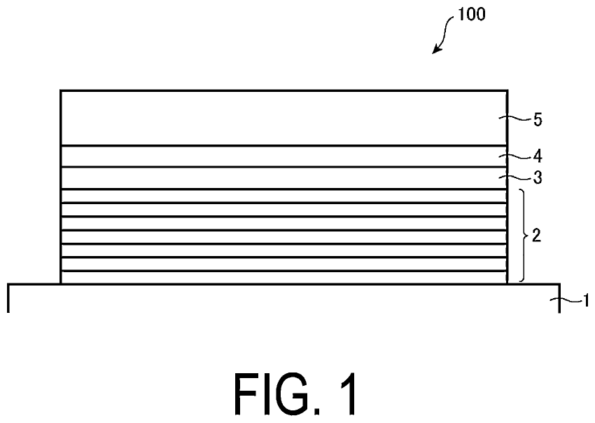

FIG. 1 is a schematic cross-sectional view of main components for explaining the configuration of the reflective mask blank 100 of the present embodiment. As illustrated in FIG. 1, the reflective mask blank 100 includes a substrate 1, a multilayer reflective film 2, a protective film 3, a buffer film (first thin film) 4, and an absorber film (second thin film) 5, and has a structure in which these are layered in this order. The multilayer reflective film 2 is formed on a first main surface (front surface) side, and reflects EUV light, which is exposure light, with high reflectance. The protective film 3 is provided to protect the multilayer reflective film 2, and is made of a material having resistance to an etchant and a cleaning liquid used when patterning the buffer film 4 to be described below. The buffer film 4 and the absorber film 5 absorb the EUV light and have a phase shift function. A conductive film (not illustrated) for electrostatic chucking is formed on a second main surface (rear surface) side of the substrate 1. Note that an etching mask film may be provided on the absorber film 5.

In this specification, “the multilayer reflective film 2 is provided on the main surface of the substrate 1” includes not only a case where the multilayer reflective film 2 is disposed in contact with the surface of the substrate 1 but also a case where another film is provided between the substrate 1 and the multilayer reflective film 2. The same applies to the other films. For example, “a film B is provided on a film A” includes not only a case where the film A and the film B are disposed to be in direct contact with each other but also a case where another film is provided between the film A and the film B. In this specification, for example, “the film A is disposed in contact with a surface of the film B” means that the film A and the film B are disposed to be in direct contact with each other without another film interposed between the film A and the film B.

Hereinafter, the present embodiment will be described for each layer.

### Substrate 1

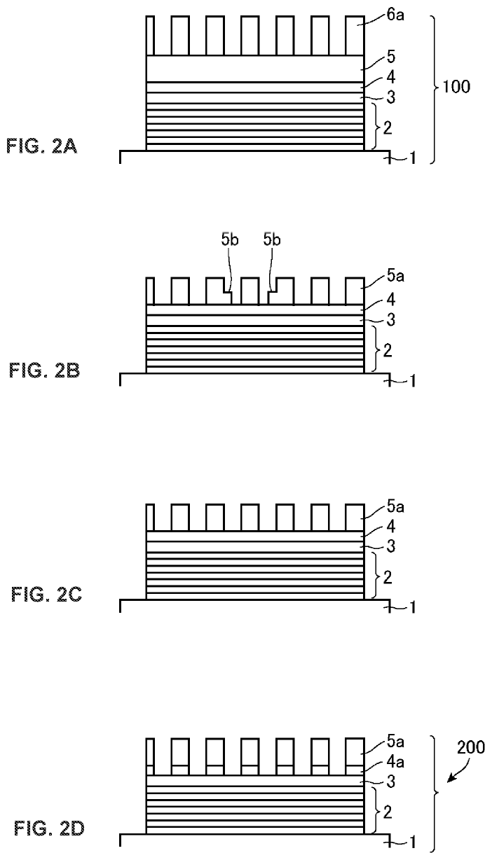

To prevent distortion of an absorber pattern (transfer pattern) 5a (see FIGS. 2A-2D) due to heat during exposure with EUV light, a material with a low coefficient of thermal expansion in the range of 0±5 ppb/° C. is preferably used for the substrate 1. Examples of materials having a low coefficient of thermal expansion in this range include SiO₂—TiO₂-based glass and multicomponent-based glass ceramics.

A surface treatment is applied to the first main surface of the substrate 1, on which a transfer pattern (a buffer pattern 4a and the absorber pattern 5a to be described below) is to be formed, in order to achieve a high degree of flatness from the viewpoint of obtaining at least pattern transfer precision and positioning precision. In the case of EUV exposure, the flatness is preferably 0.1 μm or less, more preferably 0.05 μm or less, and particularly preferably 0.03 μm or less in a 132 mm×132 mm region of the main surface (first main surface) of the substrate 1 on which the transfer pattern is to be formed. The second main surface opposite to the side on which the transfer pattern is to be formed is a surface that is electrostatically chucked when the reflective mask 200 is set in an exposure apparatus, and the flatness is preferably 0.1 μm or less, more preferably 0.05 μm or less, and particularly preferably 0.03 μm or less in the 132 mm×132 mm region. Note that the flatness of the second main surface in the reflective mask blank 100 is preferably 1 μm or less, more preferably 0.5 μm or less, and particularly preferably 0.3 μm or less in a 142 mm×142 mm region.

It is also extremely important for the substrate 1 to have high surface smoothness. The surface roughness of the first main surface of the substrate 1 is preferably 0.1 nm or less in terms of root-mean-square roughness (RMS). Note that the surface smoothness can be measured using an atomic force microscope.

The substrate 1 preferably has high rigidity in order to suppress deformation due to film stress of films (the multilayer reflective film 2 and the like) formed on the substrate 1. Particularly, the substrate 1 preferably has a high Young's modulus of 65 GPa or more.

### Multilayer Reflective Film 2

The multilayer reflective film 2 provides a reflective mask 200 with a function of reflecting EUV light, and is a multilayer film in which layers each including elements with different refractive indexes as main components are layered periodically.

In general, a multilayer film in which a thin film (high refractive index layer) of a light element, which is a high refractive index material or a compound thereof and a thin film (low refractive index layer) of a heavy element, which is a low refractive index material or a compound thereof are alternately layered as one cycle and approximately 40 to 60 of the cycles are layered is used for the multilayer reflective film 2. The multilayer film may be formed by forming a layered structure with a high refractive index layer and a low refractive index layer, in which the high refractive index layer and the low refractive index layer are layered as one cycle in this order from the substrate 1 side, and then layering a plurality of cycles of the layered structure. The multilayer film may be formed by forming a layered structure with a low refractive index layer and a high refractive index layer, in which the low refractive index layer and the high refractive index layer are layered as one cycle in this order from the substrate 1 side, and then layering a plurality of cycles of the layered structure. Note that the outermost layer of the multilayer reflective film 2, that is, the surface layer of the multilayer reflective film 2 on the side opposite to the substrate 1 is preferably a high refractive index layer. When the multilayer film described above is formed by forming a layered structure with a high refractive index layer and a low refractive index layer, in which the high refractive index layer and the low refractive index layer are layered as one cycle in this order from the substrate 1 side, and layering a plurality of cycles of the layered structure, the uppermost layer is a low refractive index layer. In this case, when the low refractive index layer constitutes the outermost surface of the multilayer reflective film 2, the low refractive index layer is easily oxidized, and the reflectance of the reflective mask 200 decreases. Therefore, the multilayer reflective film 2 is preferably formed by further forming a high refractive index layer on the uppermost low refractive index layer. On the other hand, when the multilayer film described above is formed by forming a layered structure with a low refractive index layer and a high refractive index layer, in which the low refractive index layer and the high refractive index layer are layered as one cycle and layering a plurality of cycles of the layered structure, since the uppermost layer is a high refractive index layer, the configuration may be left as it is.

In the present embodiment, a layer containing silicon (Si) is employed as the high refractive index layer. As the material containing Si, an Si compound containing Si, boron (B), carbon (C), nitrogen (N), and oxygen (O) can be used in addition to the material containing only Si. Using layers containing Si for a high refractive index layers makes it possible to produce the reflective mask 200 for EUV lithography with excellent reflectance with respect to EUV light. In the present embodiment, a glass substrate is preferably used as the substrate 1. Si is also excellent in adhesion to the glass substrate. As the low refractive index layer, pure metal selected from molybdenum (Mo), ruthenium (Ru), rhodium (Rh), and platinum (Pt), or an alloy thereof is used. An Mo/Si cyclic layered film in which an Mo film and an Si film are alternately layered as one cycle and approximately 40 to 60 of cycles are layered is used for the multilayer reflective film 2 for EUV light having a wavelength of from 13 nm to 14 nm, for example. Note that the high refractive index layer, which is the uppermost layer of the multilayer reflective film 2, may be made of silicon (Si).

The reflectance of the multilayer reflective film 2 by itself is typically 65% or more, and the upper limit of the reflectance is typically 73%. Note that the film thickness and cycle of each constituent layer of the multilayer reflective film 2 may be appropriately selected according to an exposure wavelength, and are selected to satisfy the Bragg reflection law. A plurality of high refractive index layers and a plurality of low refractive index layers are present in the multilayer reflective film 2, but the thicknesses of the high refractive index layers may differ from each other and the film thicknesses of the low refractive index layers may differ from each other. The film thickness of the Si layer of the outermost surface of the multilayer reflective film 2 can be adjusted within a range that does not result in a decrease in reflectance. The film thickness of the Si layer (high refractive index layer) of the outermost surface can be in the range from 3 nm to 10 nm.

A method of forming the multilayer reflective film 2 is known in the art. For example, each layer of the multilayer reflective film 2 can be formed using an ion beam sputtering method. In the case of the Mo/Si cyclic multilayer film described above, an Si film having a thickness of about 4 nm is first formed on the substrate 1 by the ion beam sputtering method using an Si target, for example. Subsequently, an Mo film having a thickness of about 3 nm is formed by using an Mo target. With this Si film/Mo film as one cycle, 40 to 60 of the cycles are layered to form the multilayer reflective film 2 (outermost layer is the Si layer). Note that, for example, when the cycles of the multilayer reflective film 2 are 60 cycles, the number of steps increases compared to a case where the cycles of the multilayer reflective film 2 are 40 cycles, but the reflectance for EUV light can be increased. Furthermore, when forming the multilayer reflective film 2, the multilayer reflective film 2 is preferably formed by supplying krypton (Kr) ion particles from an ion source and performing ion beam sputtering.

### Protective Film 3

The reflective mask blank 100 of the present embodiment preferably includes the protective film 3 between the multilayer reflective film 2 and the buffer film 4.

To protect the multilayer reflective film 2 from dry etching and cleaning in a step of manufacturing the reflective mask 200 to be described below, the protective film 3 can be formed on the multilayer reflective film 2 or in contact with the surface of the multilayer reflective film 2. The protective film 3 is made of a material having resistance to an etchant used when patterning the buffer film 4 and a cleaning liquid. Since the protective film 3 is formed on the multilayer reflective film 2, damage to the surface of the multilayer reflective film 2 can be suppressed when the reflective mask 200 (EUV mask) is manufactured by using the substrate 1 including the multilayer reflective film 2 and the protective film 3. Therefore, the reflectance characteristics of the multilayer reflective film 2 with respect to EUV light are improved.

The protective film 3 preferably contains ruthenium. A material of the protective film 3 may be pure Ru metal, may be an Ru alloy containing Ru and at least one metal selected from titanium (Ti), niobium (Nb), molybdenum (Mo), zirconium (Zr), yttrium (Y), boron (B), lanthanum (La), cobalt (Co), and rhenium (Re), or may contain nitrogen. Such a protective film 3 is particularly effective when the buffer film 4 is patterned by dry etching using a chlorine-based gas (Cl-based gas). The protective film 3 is preferably made of a material having an etching selectivity of the buffer film 4 with respect to the protective film 3 (etching rate of the buffer film 4/etching rate of the protective film 3) of 1.5 or more, and preferably 3 or more in dry etching using the chlorine-based gas. Although FIG. 1 illustrates a case where the protective film 3 is a single layer, the protective film 3 may have a layered structure with three or more layers. For example, in the protective film 3, the lowermost layer and the uppermost layer may be layers made of a substance containing Ru, and metal other than Ru or an alloy may be interposed between the lowermost layer and the uppermost layer. On the other hand, a material selected from silicon-based materials such as silicon (Si), a material containing silicon (Si) and oxygen (O), a material containing silicon (Si) and nitrogen (N), and a material containing silicon (Si), oxygen (O), and nitrogen (N) can be used for the protective film 3.

In EUV lithography, there are few substances transparent to exposure light, and this makes it technically difficult to provide an EUV pellicle for preventing foreign substances from adhering to a mask pattern surface. Therefore, pellicleless processes that do not utilize a pellicle became the mainstream. Furthermore, in the EUV lithography, exposure contamination in which carbon films are deposited or oxide films are grown on a mask due to EUV exposure, occurs. Therefore, when the reflective mask 200 for EUV exposure is used for manufacturing semiconductor devices, it is necessary to frequently clean the mask to remove foreign matter and contaminants on the mask. Accordingly, the reflective mask 200 for EUV exposure requires incomparably greater resistance to mask cleaning than that of a transparent mask for optical lithography. Since the reflective mask 200 includes the protective film 3, the cleaning resistance to a cleaning liquid can be increased.

The film thickness of the protective film 3 is not particularly limited as long as the function of protecting the multilayer reflective film 2 can be achieved. From the viewpoint of the reflectance with respect to EUV light, the film thickness of the protective film 3 is preferably 1.0 or more and 8.0 nm or less, and more preferably 1.5 nm or more and 6.0 nm or less.

As a method of forming the protective film 3, a method similar to a known film forming method can be employed without particular limitation. Specific examples of the method include a sputtering method and an ion beam sputtering method.

### Buffer Film (First Thin Film) and Absorber Film (Second Thin Film)

In the reflective mask blank 100 of the present embodiment, the buffer film (first thin film) 4 and the absorber film (second thin film) 5 are formed on the multilayer reflective film 2 or on the protective film 3 formed on the multilayer reflective film 2. In the state of the reflective mask 200, the buffer pattern 4a is formed in the buffer film 4, the absorber pattern 5a is formed in the absorber film 5, and the buffer pattern 4a and the absorber pattern 5a constitute a transfer pattern.

The relative reflectance R₂ of the absorber film 5 relative to the reflectance of the multilayer reflective film 2 with respect to the light having a wavelength of 13.5 nm (EUV exposure light or EUV light for inspection) is 3% or more. When the extinction coefficient of the buffer film 4 with respect to the light having a wavelength of 13.5 nm is k₁ and the thickness of the buffer film 4 is d₁ [nm], the relationship of Formula 1 below is satisfied.

21.5×k₁²×d₁²−52.5×k₁×d₁+32.1>R₂ (Formula 1)

In the reflective mask 200 to be described below in the present embodiment, portions where the buffer film 4 and the absorber film 5 (the buffer pattern 4a and the absorber pattern 5a) are provided absorb and attenuate the EUV light while reflecting a part of the light to the extent of not adversely affecting a pattern transfer. On the other hand, in opening portions (where the buffer film 4 and the absorber film 5 are not present), the EUV light is reflected from the multilayer reflective film 2 (from the multilayer reflective film 2 via the protective film 3 when the protective film 3 is present). The reflected light from the portions, where the buffer film 4 and the absorber film 5 are formed, forms a desired phase difference with respect to the reflected light from the opening portions. The buffer film 4 and the absorber film 5 are formed so that the phase difference between the reflected light from the buffer film 4 and the absorber film 5 and the reflected light from the multilayer reflective film 2 is from 130° to 230°. These two types of light having an inverted phase difference of approximately 180° or approximately 220° interfere with each other at the edges of the pattern, thereby improving the image contrast of a projected optical image. This improvement in the image contrast increases the resolution and improves various exposure-related tolerances such as exposure amount tolerance and focus tolerance.

Hereinafter, each film will be described.

### Buffer Film (First Thin Film)

In the reflective mask blank 100 of the present embodiment, the buffer film (first thin film) 4 is formed on the multilayer reflective film 2 or on the protective film 3 formed on the multilayer reflective film 2.

The buffer film 4 preferably contains a metal element. The metal element can be a metal element in a broad sense, and can be selected from alkali metals, alkaline earth metals, transition metals, and semimetals. The buffer film 4 has etching selectivity with respect to the multilayer reflective film 2 (etching selectivity with respect to the protective film 3 when the protective film 3 is formed), and can be selected from the above-described metal element in a broad sense as long as the relationship of Formula 1 above is satisfied.

The buffer film (first thin film) 4 preferably contains a metal element and at least one element of oxygen and nitrogen. When oxygen or nitrogen is contained, the extinction coefficient can be reduced and the degree of freedom in design can be increased. When oxygen or nitrogen is contained in advance, expansion or deformation due to oxidation of the pattern formed in the buffer film 4 can be suppressed.

The thickness d₁ of the buffer film 4 is preferably 1 nm or more, and more preferably 3 nm or more. This is because damage to the multilayer reflective film 2 or the protective film 3 can be suppressed when defect repair is performed on the absorber pattern 5a. On the other hand, the thickness d₁ of the buffer film 4 is preferably 30 nm or less, more preferably 20 nm or less, and further preferably 15 nm or less. This is because the upper limit value of the relative reflectance of the absorber pattern 5a required for making the above contrast larger than 40% increases, and the degree of freedom in designing the absorber film 5 increases. This is also because damage to the absorber pattern 5a and progress of side etching can be suppressed.

The material of the buffer film 4 is not particularly limited as described above; however, a tantalum-based material or a chromium-based material can be preferably used. As the tantalum-based material, in addition to tantalum metal, a material in which one or more elements selected from nitrogen (N), oxygen (O), boron (B), and carbon (C) are contained in tantalum (Ta) is preferably employed. Among them, the tantalum-based material preferably contains tantalum (Ta) and at least one element selected from oxygen (O) and boron (B). When the buffer film 4 is made of a material containing chromium, in addition to chromium metal, a material in which one or more elements selected from oxygen (O), nitrogen (N), carbon (C), boron (B), and fluorine (F) are contained in chromium (Cr) is preferably employed. Particularly, a material containing nitride of chromium (Cr) is preferable.

The refractive index n₁ of the buffer film 4 is preferably 0.975 or less, and more preferably 0.955 or less. Furthermore, the refractive index n₁ of the buffer film 4 is preferably 0.890 or more, and more preferably 0.910 or more.

The extinction coefficient k₁ of the buffer film 4 is preferably 0.05 or less, more preferably 0.04 or less, and further preferably 0.03 or less. From the results of an optical simulation, it is presumed that the light intensity of the light reflected from the multilayer reflective film 2 is greater than that of the light reflected from the buffer film 4 for the light having a wavelength of 13.5 nm, and that the light reflected from the buffer film 4 decreases as the extinction coefficient k₁ of the buffer film 4 increases. By setting the extinction coefficient k₁ in the above range, it is presumed that a decrease in the light reflected from the buffer film 4 can be suppressed, which is preferable.

### Absorber Film (Second Thin Film) 5

In the reflective mask blank 100 of the present embodiment, the absorber film 5 is formed on the buffer film 4. As described above, the relative reflectance R₂ of the absorber film 5 relative to the reflectance of the multilayer reflective film 2 with respect to the light having a wavelength of 13.5 nm (EUV exposure light or EUV light for inspection) is 3% or more. The relative reflectance R₂ is calculated while including not only the light reflected by the absorber film 5 (strictly, including both the light reflected by the surface of the absorber film 5 and the light reflected by the interface between the absorber film 5 and the buffer film 4) but also the light reflected by the buffer film 4 (light reflected by the interface between the buffer film 4 and the protective film 3). That is, the relative reflectance R₂ can be defined as a surface reflectance in the layered structure with the buffer film 4 and the absorber film 5.

The relative reflectance R₂ is preferably 32% or less. This is to secure a sufficient contrast in a mask inspection for the light having a wavelength of 13.5 nm and to secure a sufficient contrast in a pattern image at the time of exposure and transfer.

Although it depends on the pattern and exposure conditions, to obtain a phase shift effect, the absolute reflectance of the transfer pattern (the buffer pattern 4a and the absorber pattern 5a) with respect to EUV light preferably ranges from 4% to 27%, and more preferably ranges from 10% to 17%.

The absorber film 5 of the present embodiment preferably contains a metal element. Although not particularly limited, for example, the absorber film 5 may be made of a material containing ruthenium (Ru) and chromium (Cr). More preferably, a material in which at least one element selected from nitrogen (N), oxygen (O), boron (B), and carbon (C) is contained in ruthenium (Ru) and chromium (Cr) is used for the absorber film 5.

On the other hand, a material in which at least one element selected from tellurium (Te), antimony (Sb), platinum (Pt), iodide (I), bismuth (Bi), iridium (Ir), osmium (Os), tungsten (W), rhenium (Re), tin (Sn), indium (In), polonium (Po), iron (Fe), gold (Au), mercury (Hg), gallium (Ga), and aluminum (Al) is contained in tantalum (Ta) may be used for the absorber film 5. The absorber film 5 may also be made of a material containing tantalum (Ta) and iridium (Ir). More preferably, a material in which at least one element selected from nitrogen (N), oxygen (O), boron (B), and carbon (C) is contained in ruthenium (Ru) and chromium (Cr) is used for the absorber film 5.

The phase difference and the reflectance of the absorber film 5 can be adjusted by changing a refractive index n₂, an extinction coefficient k₂, and a film thickness. The film thickness of the absorber film 5 is preferably 60 nm or less, more preferably 50 nm or less, and further preferably 45 nm or less. The film thickness of the absorber film 5 is preferably 20 nm or more. Note that when the protective film 3 is provided, the phase difference and the reflectance of the absorber film 5 can also be adjusted in consideration of the refractive index n, the extinction coefficient k, and the film thickness of the protective film 3.

The refractive index n₂ of the absorber film 5 with respect to the light having a wavelength of 13.5 nm is preferably 0.870 or more, and more preferably 0.885 or more. The refractive index n₂ of the absorber film 5 is preferably 0.955 or less, and more preferably 0.940 or less. The extinction coefficient k₂ of the absorber film 5 with respect to the light having a wavelength of 13.5 nm is preferably 0.01 or more, and more preferably 0.02 or more. The extinction coefficient k₂ of the absorber film 5 is preferably 0.05 or less, and more preferably 0.04 or less.

The absorber film 5 made of the above-described predetermined material can be formed by a known method such as a sputtering method such as a DC sputtering method and an RF sputtering method, and a reactive sputtering method using oxygen gas or the like. A target may contain one kind of metal, and when the absorber film 5 is composed of two or more kinds of metals, an alloy target containing two or more kinds of metals (for example, Ru and Cr) can be used. When the absorber film 5 is composed of two or more kinds of metals, a thin film constituting the absorber film 5 can be formed by co-sputtering using an Ru target and a Cr target.

The absorber film 5 may be a multilayer film including two or more layers.

### Etching Mask Film

The etching mask film can be formed on the absorber film 5 or in contact with the surface of the absorber film 5. As a material of the etching mask film, a material that increases the etching selectivity of the absorber film 5 with respect to the etching mask film is used. The “etching selectivity of B with respect to A” refers to the ratio of an etching rate of A, which is a layer that does not need to be etched (layer serving as a mask), and an etching rate of B which is a layer that needs to be etched. Specifically, it is specified by Formula “etching selectivity of B with respect to A=etching rate of B/etching rate of A”. Furthermore, “high selectivity” means that the value of the above-defined selectivity is greater than that of an object to be compared. The etching selectivity of the absorber film 5 with respect to the etching mask film is preferably 1.5 or more, and more preferably 3 or more.

The absorber film 5 made of an Ru-based material in the present embodiment can be etched by dry etching using a chlorine-based gas containing oxygen, or an oxygen gas. Silicon (Si) or a material of a silicon compound can be used as a material having a high etching selectivity of the absorber film 5 made of the Ru-based material with respect to the etching mask film.

Examples of the silicon compound that can be used for the etching mask film include a material containing silicon (Si) and at least one element selected from nitrogen (N), oxygen (O), carbon (C), and hydrogen (H), and a material such as metal silicon (metal silicide) or a metal silicon compound (metal silicide compound) in which metal is contained in silicon or a silicon compound. Examples of the metal silicon compound include a material containing a metal, Si, and at least one element selected from N, O, C, and H.

The film thickness of the etching mask film is expected to be 2 nm or more from the viewpoint of obtaining a function as an etching mask for forming a transfer pattern in the absorber film 5 with high precision. The film thickness of the etching mask film is expected to be 15 nm or less from the viewpoint of reducing the thickness of a resist film.

### Conductive Film

A conductive film (not illustrated) for electrostatic chucking is generally formed on the second main surface (rear surface) side of the substrate 1 (on the side opposite to the surface on which the multilayer reflective film 2 is formed). The electrical properties (sheet resistance) required for the conductive film for electrostatic chucking are typically 100Ω/□ (Ω/square) or less. The conductive film can be formed by a magnetron sputtering method or an ion beam sputtering method using a target made of metal such as chromium (Cr) and tantalum (Ta) and an alloy, for example.

A material of the conductive film containing chromium (Cr) is preferably a Cr compound containing Cr and further containing at least one selected from boron (B), nitrogen (N), oxygen (O), and carbon (C).

As a material of the conductive film containing tantalum (Ta), Ta (tantalum), an alloy containing Ta, or a Ta compound in which at least one of boron, nitrogen, oxygen, and carbon is contained in any one of these materials is preferably used.

The thickness of the conductive film is not particularly limited as long as the film can satisfactorily serve as an electrostatic chuck. The thickness of the conductive film ranges typically from 10 nm to 200 nm. The conductive film also serves to adjust the stress on the second main surface side of the mask blank 100. That is, the conductive film is adjusted to obtain a flat reflective mask blank 100 by balancing the stress from various films formed on the first main surface side.

### Reflective Mask 200 and Method of Manufacturing Thereof

In the reflective mask 200 of the present embodiment, the transfer pattern (the buffer pattern 4a and the absorber pattern 5a) is formed in the buffer film 4 and the absorber film 5 of the reflective mask blank 100. The buffer film 4 and the absorber film 5, in which the transfer pattern (the buffer pattern 4a and the absorber pattern 5a) is formed, are the same as the buffer film 4 and the absorber film 5 of the reflective mask blank 100 of the present embodiment described above. By patterning the buffer film 4 and the absorber film 5 of the reflective mask blank 100 of the present embodiment described above, the transfer pattern (the buffer pattern 4a and the absorber pattern 5a) can be formed. The patterning of the buffer film 4 and the absorber film 5 can be performed using predetermined dry etching gases. The buffer pattern 4a and the absorber pattern 5a of the reflective mask 200 can absorb the EUV light and reflect a part of the EUV light with a predetermined phase difference with respect to the light reflected from opening portions (where the buffer pattern 4a and the absorber pattern 5a are not formed). As the predetermined dry etching gas, a mixed gas of a chlorine-based gas and an oxygen gas, an oxygen gas, a fluorine-based gas, or the like can be used. To pattern the buffer pattern 4a and the absorber pattern 5a, an etching mask film can be provided on the buffer pattern 4a and the absorber pattern 5a, if necessary. In this case, the buffer pattern 4a and the absorber pattern 5a can be formed by dry-etching the buffer film 4 and the absorber film 5 by using an etching mask pattern as a mask.

A method of manufacturing the reflective mask 200 by using the reflective mask blank 100 of the present embodiment will be described.

The reflective mask blank 100 is prepared, and a resist film is formed on the absorber film 5 on the first main surface of the reflective mask blank 100 (the formation of the resist film is not necessary when the reflective mask blank 100 includes a resist film). A desired transfer pattern is written (exposed) on the resist film, and is further developed and rinsed to form a predetermined resist pattern 6a (resist film having a transfer pattern) (see FIG. 2A).

Subsequently, using the resist pattern 6a as a mask, the absorber film 5 is etched to form the absorber pattern 5a (absorber film 5 having a transfer pattern). Since the buffer film 4 has sufficient etching selectivity with respect to this etching, the buffer film 4 remains over the whole surface. After the absorber pattern 5a is formed, the remaining resist pattern 6a is removed (when an etching mask film is formed, the etching mask film is etched using the resist pattern 6a as a mask to form an etching mask pattern, the absorber pattern 5a is formed using the etching mask pattern as a mask, and the etching mask pattern is removed). In this case, a defect portion 5b may remain in the absorber pattern 5a (see FIG. 2B). Mask inspection (defect inspection) using the light having a wavelength of 13.5 nm (EUV light for inspection) is performed on the absorber pattern 5a to detect the defect portion 5b.

In the reflective mask blank 100 in the present embodiment, as described above, the relative reflectance R₂ relative to the reflectance of the multilayer reflective film 2 with respect to the light having a wavelength of 13.5 nm (EUV exposure light or EUV light for inspection) is 3% or more. When the extinction coefficient of the buffer film 4 with respect to the light having a wavelength of 13.5 nm is k₁ and the thickness of the buffer film 4 is d₁ [nm], the relationship of Formula 1 below is satisfied.

21.5×k₁²×d₁²−52.5×k₁×d₁+32.1>R₂ (Formula 1)

Therefore, a preferable contrast exceeding 40% can be secured between the absorber film 5 and the buffer film 4, and the defect portion 5b (also including a defect portion in a state where the absorber film 5 is partially etched as illustrated in the drawing), which may cause a problem in forming a transfer pattern, can be detected with high precision.

Subsequently, the detected defect portion 5b is removed by irradiating the defect portion 5b with an electron beam (charged particles) while supplying a fluorine-based gas (fluorine-containing substance) in a non-excited state to the defect portion 5b (see FIG. 2C).

Subsequently, the buffer pattern 4a (the buffer film 4 having a transfer pattern) is formed by etching the buffer film 4 using the absorber pattern 5a as a mask. Finally, the reflective mask 200 of the present embodiment is manufactured by performing wet cleaning using an acidic or alkaline aqueous solution (see FIG. 2D).

As described above, the method of manufacturing the reflective mask 200 of the present embodiment is a method of manufacturing the reflective mask 200 using the reflective mask blank 100, and includes the steps of forming the absorber pattern 5a constituting a transfer pattern in the absorber film 5 serving as the second thin film, performing a defect inspection of the absorber pattern 5a by using inspection light including light having a wavelength of 13.5 nm, performing a defect repair by irradiating the defect portion 5b detected by the defect inspection which exist in the absorber pattern 5a with charged particles while supplying a fluorine-containing substance to the defect portion 5b, and forming the buffer pattern 4a constituting the transfer pattern in the buffer film serving as the first thin film after the defect repair.

### Method of Manufacturing Semiconductor Device

The present embodiment is a method of manufacturing a semiconductor device, which includes transferring a transfer pattern to a resist film on a semiconductor substrate by exposure, using the reflective mask 200 described above or the reflective mask 200 manufactured by the method of manufacturing the reflective mask 200 described above. The semiconductor device can be manufactured by setting the reflective mask 200 of the present embodiment in an exposure apparatus including an exposure light source of EUV light and transferring a transfer pattern to a resist film formed on a transfer target substrate. Therefore, a semiconductor device including a fine and highly precise transfer pattern can be manufactured.

### EXAMPLES

Hereinafter, examples will be described with reference to the drawings. The present embodiment is not limited to these examples. Note that the same reference numerals are used for components that are the same in the examples, and descriptions thereof will be simplified or omitted.

### Example 1

As Example 1, a method of manufacturing a reflective mask blank 100 will be described.

An SiO₂—TiO₂-based glass substrate which is a glass substrate that exhibits low thermal expansion of 6025 size (approximately 152 mm×152 mm×6.35 mm) and in which both a first main surface and a second main surfaces were polished was prepared and used as a substrate 1. Polishing including a rough polishing step, a precision polishing step, a local processing step, and a touch polishing step was performed to obtain the flat and smooth main surfaces.

Subsequently, a conductive film made of a CrN film was formed on the second main surface (rear surface) of the SiO₂—TiO₂-based glass substrate 1 by using a magnetron sputtering (reactive sputtering) method under the following conditions. The conductive film having a film thickness of 20 nm was formed by using a Cr target in a mixed gas atmosphere of argon (Ar) gas and nitrogen (N₂) gas.

Subsequently, a multilayer reflective film 2 was formed on the main surface (first main surface) of the substrate 1 on the side opposite to the side where the conductive film was formed. The multilayer reflective film 2 formed on the substrate 1 was formed as a cyclic layered reflective film made of molybdenum (Mo) and silicon (Si) in order to produce a multilayer reflective film 2 suitable for EUV light having a wavelength of 13.5 nm. The multilayer reflective film 2 was formed by alternately layering an Mo layer and an Si layer on the substrate 1 by an ion beam sputtering method using an Mo target and an Si target in a krypton (Kr) gas atmosphere. First, an Si film having a film thickness of 4.2 nm was formed, and subsequently, an Mo film having a film thickness of 2.8 nm was formed. With this as one cycle, 40 cycles were layered, and finally an Si film having a film thickness of 4.0 nm was formed to form the multilayer reflective film 2.

Subsequently, in an Ar gas atmosphere, a protective film 3 made of an Ru film and having a film thickness of 3.5 nm was formed on the surface of the multilayer reflective film 2 by a sputtering method using an Ru target.

Subsequently, a thin film (TaBO film) made of tantalum (Ta), oxygen (O), and boron (B) was formed as a buffer film 4 in Example 1 by a DC magnetron sputtering method (reactive sputtering method). The buffer film 4 having a thickness of 6 nm was formed by using a mixed target of tantalum (Ta) and boron (B) in an atmosphere of mixed argon (Ar) and oxygen (O₂) gas.

The refractive index n₁, the extinction coefficient (imaginary part of the refractive index) k₁, and the relative reflectance R₁ of the buffer film 4 (TaBO film) of Example 1 formed as described above with respect to a wavelength of 13.5 nm were as follows.

TaBO film:n₁=0.955,k₁=0.022,R₁=80.1%

Subsequently, a thin film (RuCrN film) made of ruthenium (Ru), chromium (Cr), and nitrogen (N) was formed as an absorber film 5 by a DC magnetron sputtering method (reactive sputtering method). The absorber film 5 having a thickness of 40.0 nm was formed by using an Ru target and a Cr target in a mixed gas atmosphere of a krypton (Kr) gas and a nitrogen (N₂) gas.

The refractive index n₂, the extinction coefficient (imaginary part of the refractive index) k₂, and the relative reflectance R₂ of the absorber film 5 (RuCrN film) of Example 1 formed as described above with respect to a wavelength of 13.5 nm were as follows.

RuCrN film:n₂=0.900,k₂=0.021,R₂=19.9%

The reflective mask blank 100 of Example 1 was manufactured by the above procedure.

As a result of examining whether the buffer film 4 and the absorber film 5 in the reflective mask blank 100 of Example 1 satisfy the relationship of Formula 1, the value of the left side (21.5×k₁²×d₁²−52.5×k₁×d₁+32.1) of Formula 1 was 25.6, and the value of the right side (R₂) thereof was 19.9, which satisfied the relationship of Formula 1. The contrast between the absorber film 5 and the buffer film 4 in Example 1 was 60.2%, which was a good value exceeding 40%.

Subsequently, a reflective mask 200 of Example 1 was manufactured according to the steps illustrated in FIGS. 2A-2D by using the above reflective mask blank 100.

In the step illustrated in FIG. 2B, as a result of which mask inspection (defect inspection) using light having a wavelength of 13.5 nm (EUV light for inspection) was performed on an absorber pattern 5a in Example 1, a defect portion 5b which may cause a problem in forming a transfer pattern can be precisely detected. Thus, by irradiating the detected defect portion 5b with an electron beam while supplying a fluorine-based gas to the defect portion 5b, the defect portion 5b can be removed, so that the reflective mask 200 including a good absorber pattern 5a can be manufactured.

The reflective mask 200 produced in Example 1 was set in an EUV scanner and a wafer including a film to be processed and a resist film formed on a semiconductor substrate was subjected to EUV exposure. Subsequently, by developing the exposed resist film, a resist pattern was formed on the semiconductor substrate on which the film to be processed was formed. By performing various other steps such as transferring the resist pattern to the film to be processed by etching, forming an insulating film and a conductive film, injecting a dopant, and annealing, a semiconductor device having desired characteristics can be manufactured.

### Example 2

In Example 2, a reflective mask blank 100 having the same structure as that in Example 1 was manufactured by the same method as in Example 1 except for the buffer film 4 and the absorber film 5.

After the multilayer reflective film 2 and the protective film 3 were formed on the substrate 1 in the same manner as in Example 1, a thin film (CrN film) made of chromium (Cr) and nitrogen (N) was formed as a buffer film 4 in Example 2 by a DC magnetron sputtering method (reactive sputtering method). The buffer film 4 having a thickness of 6 nm was formed by using a chromium (Cr) target in an atmosphere of a mixed gas of argon (Ar) gas and nitrogen (N₂) gas.

The refractive index n₁, the extinction coefficient (imaginary part of the refractive index) k₁, and the relative reflectance R₁ of the buffer film 4 (CrN film) of Example 2 formed as described above with respect to a wavelength of 13.5 nm were as follows.

CrN film:n₁=0.928,k₁=0.039,R₁=67.4%

Subsequently, a thin film (IrTaO film) made of iridium (Ir), tantalum (Ta), and oxygen (O) was formed as an absorber film 5 by a DC magnetron sputtering method (reactive sputtering method). The absorber film 5 having a film thickness of 40.0 nm was formed by reactive sputtering using an Ir target and a Ta target in a mixed gas atmosphere of krypton (Kr) gas and oxygen (O₂) gas.

The refractive index n₂, the extinction coefficient (imaginary part of the refractive index) k₂, and the relative reflectance R₂ of the absorber film 5 (IrTaO film) of Example 2 formed as described above with respect to a wavelength of 13.5 nm were as follows.

IrTaO film:n₂=0.927,k₂=0.033,R₂=5.2%

The reflective mask blank 100 of Example 2 was manufactured by the above procedure.

As a result of examining whether the buffer film 4 and the absorber film 5 in the reflective mask blank 100 of Example 2 satisfy the relationship of Formula 1, the value of the left side (21.5×k₁²×d₁²−52.5×k₁×d₁+32.1) of Formula 1 was 21.0, and the value of the right side (R₂) thereof was 5.2, which satisfied the relationship of Formula 1. The contrast between the absorber film 5 and the buffer film 4 in Example 2 was 85.7%, which was a good value exceeding 40%.

Subsequently, a reflective mask 200 of Example 2 was manufactured according to the steps illustrated in FIGS. 2A-2D by using the above reflective mask blank 100.

In the step illustrated in FIG. 2B, as a result of which mask inspection (defect inspection) using light having a wavelength of 13.5 nm (EUV light for inspection) was performed on an absorber pattern 5a in Example 2, a defect portion 5b which may cause a problem in forming a transfer pattern can be precisely detected. Thus, by irradiating the detected defect portion 5b with an electron beam while supplying a fluorine-based gas to the detected defect portion 5b, the defect portion 5b can be removed, so that the reflective mask 200 including a good absorber pattern 5a can be manufactured.

The reflective mask 200 produced in Example 2 was set in an EUV scanner and a wafer including a film to be processed and a resist film formed on a semiconductor substrate was subjected to EUV exposure. Subsequently, by developing the exposed resist film, a resist pattern was formed on the semiconductor substrate, on which the film to be processed was formed. By performing various other steps such as transferring the resist pattern to the film to be processed by etching, forming an insulating film and a conductive film, injecting a dopant, and annealing, a semiconductor device having desired properties can be manufactured.

### Comparative Example 1

In Comparative Example 1, a reflective mask blank having the same structure as that in Example 1, was manufactured by the same method as in Example 1, except for a buffer film and an absorber film.

After a multilayer reflective film and a protective film were formed on a substrate in the same manner as in Example 1, a thin film (TaBO film) made of tantalum (Ta), oxygen (O), and boron (B) was formed as a buffer film in Comparative Example 1 by a DC magnetron sputtering method (reactive sputtering method). The buffer film having a thickness of 10 nm was formed by using a mixed target of tantalum (Ta) and boron (B) in an atmosphere of a mixed gas of argon (Ar) gas and oxygen (O₂) gas.

The refractive index n₁, the extinction coefficient (imaginary part of the refractive index) k₁, and the relative reflectance R₁ of the buffer film (TaBO film) of Comparative Example 1 formed as described above with respect to a wavelength of 13.5 nm were as follows.

TaBO film:n₁=0.955,k₁=0.022,R₁=60.8%

Subsequently, a thin film (RuN film) made of ruthenium (Ru) and nitrogen (N) was formed as an absorber film by a DC magnetron sputtering method (reactive sputtering method). The absorber film having a thickness of 40.0 nm, was formed by using an Ru target in a mixed gas atmosphere of krypton (Kr) gas and nitrogen (N₂) gas.

The refractive index n₂, the extinction coefficient (imaginary part of the refractive index) k₂, and the relative reflectance R₂ of the absorber film (RuN film) of Comparative Example 1 formed as described above with respect to a wavelength of 13.5 nm were as follows.

RuN film:n₂=0.890,k₂=0.016,R₂=27.4%

The reflective mask blank of Comparative Example 1 was manufactured by the above procedure.

As a result of examining whether the buffer film and the absorber film in the reflective mask blank of Comparative Example 1 satisfy the relationship of Formula 1, the value of the left side (21.5×k₁²×d₁²−52.5×k₁×d₁+32.1) of Formula 1 was 21.7, and the value of the right side (R₂) thereof was 27.4, which did not satisfy the relationship of Formula 1. The contrast between the absorber film and the buffer film in Comparative Example 1 was 37.9%, which was lower than 40%.

Subsequently, a reflective mask 200 of Comparative Example 1 was manufactured according to the steps illustrated in FIGS. 2A-2D by using the above reflective mask blank.

In the step illustrated in FIG. 2B, as a result of which mask inspection (defect inspection) using light having a wavelength of 13.5 nm (EUV light for inspection) was performed on an absorber pattern in Comparative Example 1, the defect portion which may cause a problem in forming a transfer pattern could not be precisely detected. The defect portion to be repaired could not be detected and remained in an absorber pattern and a buffer pattern, and a reflective mask having a good absorber pattern could not be manufactured.

The reflective mask produced in Comparative Example 1 was set in an EUV scanner and a wafer including a film to be processed and a resist film formed on a semiconductor substrate was subjected to EUV exposure. Subsequently, by developing the exposed resist film, a resist pattern was formed on the semiconductor substrate on which the film to be processed was formed. When the resist pattern was transferred to the film to be processed by etching, the remaining defect portion was transferred.

Therefore, unlike the cases of Examples 1 and 2, when the reflective mask produced in Comparative Example 1 was used, a semiconductor device having desired properties could not be manufactured.

### DESCRIPTION OF REFERENCE NUMERALS

1 Substrate
2 Multilayer reflective film
3 Protective film
4 Buffer film (first thin film)
4a Buffer pattern (transfer pattern)
5 Absorber film (second thin film) having phase shift function
5a Absorber pattern (transfer pattern)
5b Defect portion
6a Resist pattern
100 Reflective mask blank
200 Reflective mask

1. A reflective mask blank comprising:
a substrate; and
a multilayer reflective film,
a first thin film and
a second thin film,
in this order on a main surface of the substrate, wherein
a relative reflectance R₂ of the second thin film relative to a reflectance of the multilayer reflective film with respect to light having a wavelength of 13.5 nm is 3% or more, and
when an extinction coefficient of the first thin film with respect to the light having a wavelength of 13.5 nm is k₁ and a thickness of the first thin film is d₁ [nm], a relationship of Formula 1 is satisfied.
21.5×k₁²×d₁²−52.5×k₁×d₁+32.1>R₂ (Formula 1)

2. The reflective mask blank according to claim 1,
wherein the relative reflectance R₂ is approximately 32% or less.

3. The reflective mask blank according to claim 1,
wherein the extinction coefficient k₁ of the first thin film is approximately 0.05 or less.

4. The reflective mask blank according to claim 1,
wherein the thickness d₁ of the first thin film is 1 nm or more and 30 nm or less.

5. The reflective mask blank according to claim 1,
wherein the first thin film contains a metal element and at least one element of oxygen and nitrogen.

6. The reflective mask blank according to claim 1,
wherein the second thin film contains a metal element such that a phase difference between with respect to reflected light having a wavelength of 13.5 nm between the second thin film and the multilayer reflective film is between 130° to 230° and has a relative reflectance contrast of greater than 40% with respect to the first thin film.

7. The reflective mask blank according to claim 1, further comprising
a protective film between the multilayer reflective film and the first thin film.

8. The reflective mask blank according to claim 7,
wherein the protective film contains ruthenium.

9. A reflective mask blank comprising:
a substrate; and
a multilayer reflective film, a first thin film, and a second thin film, in this order on a main surface of the substrate, in which a transfer pattern is formed in the first thin film and the second thin film; wherein
a relative reflectance R₂ of the second thin film relative to a reflectance of the multilayer reflective film with respect to light having a wavelength of 13.5 nm is 3% or more and a phase difference between with respect to reflected light having a wavelength of 13.5 nm between the second thin film and the multilayer reflective film is between 130° to 230°, and
wherein a contrast of the first thin film and second thin film with respect to light having a wavelength of 13.5 nm is greater than 40%.

10. A method of manufacturing a reflective mask using the reflective mask blank that comprises a substrate, a multilayer reflective film, a protective film, a first thin film, and a second thin film in this order on a main surface of the substrate, method comprising:
forming a transfer pattern in the second thin film without substantially forming the transfer pattern in the first thin film;
performing a defect inspection of the transfer pattern by using inspection light including light having a wavelength of 13.5 nm with respect to the second thin film in which the transfer pattern is formed;
performing a defect repair by irradiating defects detected by the defect inspection which exist in the transfer pattern of the second thin film with charged particles while supplying a fluorine-containing substance to the defects; and
forming another transfer pattern in the first thin film after the defect repair.

11. (canceled)

12. (canceled)

13. The reflective mask blank according to claim 9,
wherein the relative reflectance R₂ is approximately 32% or less.

14. The reflective mask blank according to claim 9,
wherein an extinction coefficient k₁ of the first thin film is approximately 0.05 or less.

15. The reflective mask blank according to claim 9,
wherein a thickness d₁ of the first thin film is 1 nm or more and 30 nm or less.

16. The reflective mask blank according to claim 9,
wherein the first thin film contains a metal element and at least one element of oxygen and nitrogen.

17. The reflective mask blank according to claim 9 further comprising
a protective film between the multilayer reflective film and the first thin film.

18. The reflective mask blank according to claim 9 wherein when an extinction coefficient of the first thin film with respect to the light having a wavelength of 13.5 nm is k₁ and a thickness of the first thin film is d₁ [nm], a relationship of Formula 1 is satisfied.
21.5×k₁²×d₁²−52.5×k₁×d₁+32.1>R₂ (Formula 1)

19. The reflective mask blank according to claim 9,
wherein the second film comprises an alloy of one of chromium and ruthenium or tantalum and boron.

20. The reflective mask blank according to claim 1,
wherein the second film comprises an alloy of one of chromium and ruthenium or tantalum and boron.
